(19) United States
(12) Patent Application Publication
(10) Pub. No.: US 2013/0305985 A1
(43) Pub. Date: Nov. 21, 2013

(54) PLASMA PROCESSING DEVICE

(71) Applicant: Kazuhiko Katsumata, Tokyo (JP)

(72) Inventor: Kazuhiko Katsumata, Tokyo (JP)

(21) Appl. No.: 13/981,836

(22) PCT Filed: Feb. 2, 2012
(86) PCT No.: PCT/JP2012/052361

§ 371 Date: Jul. 25, 2013

(30) Foreign Application Priority Data
Feb. 2, 2011 (JP) 2011-020665

(51) Int. Cl. C23C 16/448

(52) U.S. Cl. CPC C23C 16/448
USPC 118/47

(57) ABSTRACT

Provided is a plasma processing device (S1) configured to perform surface reforming on a workpiece (X) made of a metal material in a vacuum furnace (1) by plasma includes movable power feeding devices (14 and 15) that are movable in the vacuum furnace (1).

### TECHNICAL FIELD

The present invention relates to a plasma processing device.

This application claims priority to and the benefit of Japanese Patent Application No. 2011-20665 filed on Feb. 2, 2011, the disclosure of which is incorporated herein by reference.

### BACKGROUND ART

A plasma processing device configured to reform a surface of a workpiece made of metal materials using plasma has been used in the related art. The plasma processing device includes a vacuum furnace as described in, for example, Patent Document 1. When plasma is generated in the vacuum furnace in a low pressure environment, the reforming of the surface of the workpiece, such as carburization treatment, using plasma is performed.

### CITATION LIST

### Patent Document

[Patent Document 1] Japanese Unexamined Patent Application, First Publication No. 2009-149961

### SUMMARY OF INVENTION

### Technical Problem

In the plasma processing device as described above, the workpiece is usually mounted on a conductive tray, and is thus placed in the vacuum furnace. In addition, an inner wall of the vacuum furnace is grounded and negative voltage is applied to the tray. As a result, an electric field is formed between the inner wall and the workpiece, such that a processing gas is in a plasma state and the surface of the workpiece is reformed.

However, types of workpieces treated by plasma in the plasma processing device are quite various. Therefore, the distance up to the inner wall of the vacuum furnace differs according to the workpiece. The change in the distance from the workpiece to the inner wall of the vacuum furnace means a change in electric field formed between the workpiece and the inner wall of the vacuum furnace. Therefore, the plasma processing environment is changed and thus deviations occur in the surface characteristics of the treated workpiece.

Further, even when workpieces having the same shape are intended to be treated, in order to change the surface characteristics or the processing time of the workpiece, there may be cases in which there is a desire to intentionally change the formed electric field.

However, in the plasma processing device of the related art, a power feeding point to the tray or the inner wall of the vacuum furnace may not be changed. Therefore, eventually, the electric field may not be optionally changed as described above and it is difficult to suppress the deviations in the surface characteristics of the workpiece or intentionally change the surface characteristics of the workpiece.

In consideration of the above-mentioned circumstances, it is an object of the present invention to provide a plasma processing device configured to perform surface reforming on a workpiece using plasma in a vacuum furnace to be able to optionally change the strength of an electric field for generating plasma, thereby improving the degree of freedom in the surface reforming of the workpiece.

### Solution to Problem

As measures for solving the above object, the present invention employs the following configurations.

According to a first aspect of the present invention, a plasma processing device is configured to perform surface reforming on a workpiece made of a metal material in a vacuum furnace by plasma, and includes: a first power feeding device that applies a first voltage to the workpiece; and a second power feeding device that applies a second voltage different from the first voltage to a metal body disposed to face the workpiece, in which at least one of the first power feeding device and the second power feeding device is configured as a movable power feeding device that is movable in the vacuum furnace.

According to a second aspect of the present invention, in the plasma processing device according to the first aspect of the present invention, the movable power feeding device includes a conductive bar member which is inserted into the vacuum furnace from an outside of the vacuum furnace and a conductive net member which is connected to the bar member.

According to a third aspect of the present invention, in the plasma processing device according to the second aspect of the present invention, a plurality of the net members is provided.

According to a fourth aspect of the present invention, in the plasma processing device according to any one of the first to third aspects of the present invention, the movable power feeding device is disposed to be closer to an opening and closing door than a center of the vacuum furnace.

According to a fifth aspect of the present invention, in the plasma processing device according to any one of the first to fourth aspects of the present invention, the metal body to which the second voltage is applied by the second power feeding device is an electrode which is detachably put in and taken out of the vacuum furnace.

According to a sixth aspect of the present invention, in the plasma processing device according to any one of the first to fifth aspects of the present invention, a mounting part that mounts the workpiece in the vacuum furnace is insulated.

According to a seventh aspect of the present invention, in the plasma processing device according to any one of the first to sixth aspects of the present invention, the plasma processing device further includes a heater which is installed in the vacuum furnace, a carburization gas supply device that supplies a carburization gas to an inside of the vacuum furnace, and a cooling device that cools the inside of the vacuum furnace.

### Advantageous Effects of Invention

In the present invention, at least one of a first power feeding device applying a first voltage to a workpiece and a second power feeding device applying a second voltage different from the first voltage to a metal body disposed to face the workpiece is configured as a movable power feeding device that is movable in the vacuum furnace.

According to the present invention, the feeding point to the tray or the inner wall of the vacuum furnace can be changed using the movable power feeding device.

Further, the metal body having any shape is disposed to face the workpiece, such that power may be fed to the metal body.

Therefore, according to the present invention, the strength of an electric field for generating plasma can be optionally changed, such that the degree of freedom in the surface reforming of the workpiece can be improved.

### BRIEF DESCRIPTION OF DRAWINGS

FIG. 1 is a schematic configuration diagram of a plasma processing device according to an embodiment of the present invention.

FIG. 2 is a side cross-sectional view of a vacuum furnace included in the plasma processing device according to the embodiment of the present invention.

FIG. 3A is a front cross-sectional view of the vacuum furnace included in the plasma processing device according to the embodiment of the present invention.

FIG. 3B is a front cross-sectional view of the vacuum furnace included in the plasma processing device according to the embodiment of the present invention.

FIG. 4 is an enlarged view of a main part including a first power feeder of the vacuum furnace included in the plasma processing device according to the embodiment of the present invention.

FIG. 5A is an enlarged view of a main part including a second power feeder of the vacuum furnace included in the plasma processing device according to the embodiment of the present invention.

FIG. 5B is an enlarged view of a main part including the second power feeder of the vacuum furnace included in the plasma processing device according to the embodiment of the present invention.

### DESCRIPTION OF EMBODIMENTS

Hereinafter, a plasma processing device according to an embodiment of the present invention will be described with reference to the accompanying drawings. Meanwhile, in the following description, the scale of each member is appropriately changed to make each member identifiable.

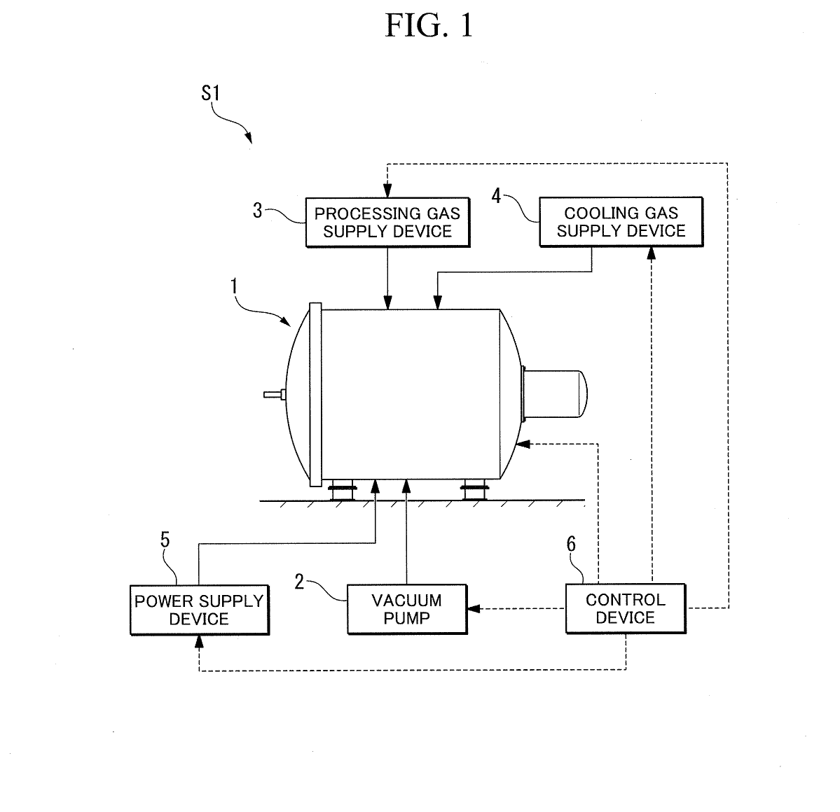

FIG. 1 is a schematic configuration diagram of a plasma processing device S1 according to the present embodiment. As illustrated in FIG. 1, the plasma processing device S1 of the present embodiment includes a vacuum furnace 1, a vacuum pump 2, a processing gas supply device 3, a cooling gas supply device 4, a power supply device 5, and a control device 6.

The vacuum furnace 1 treats a workpiece X mounted on a tray made of metal materials therein.

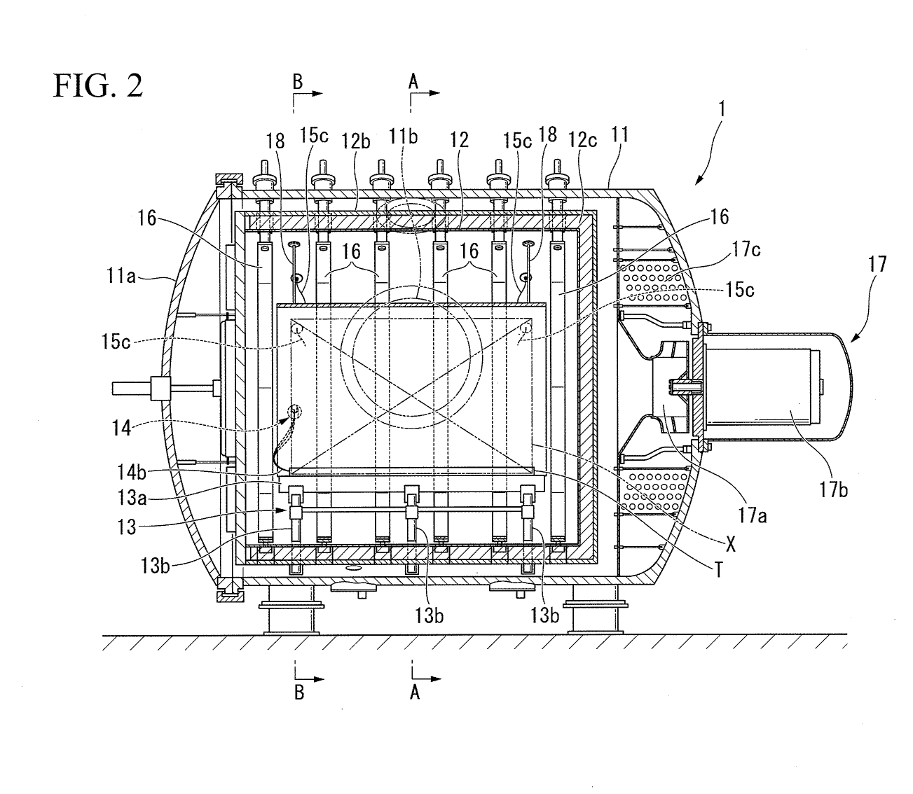

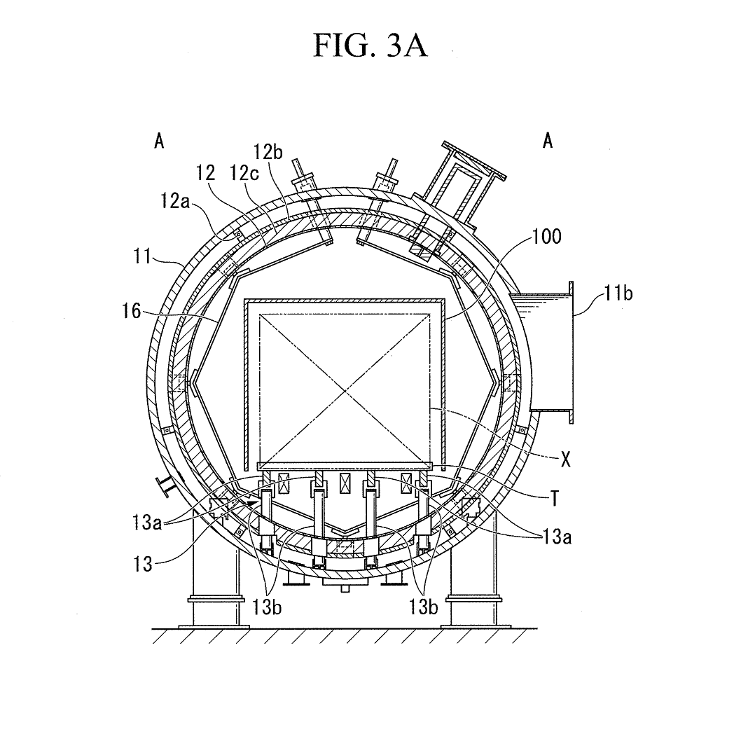

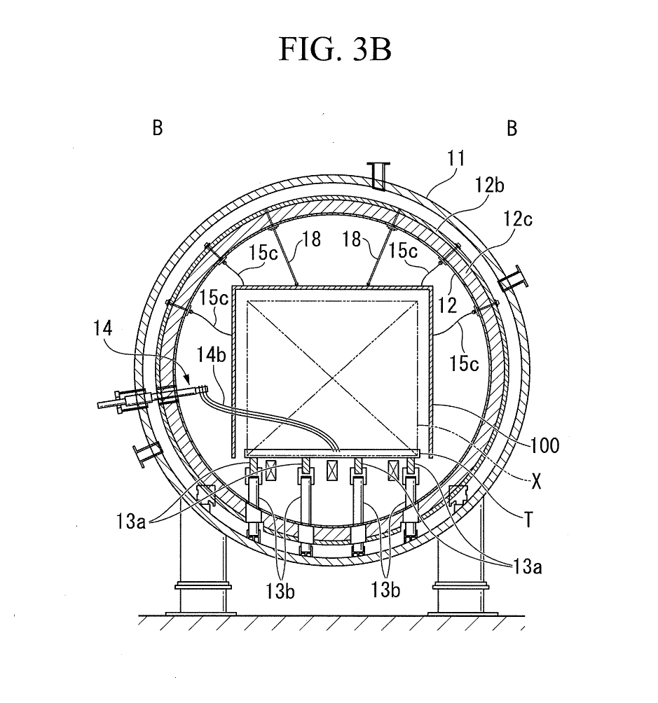

FIG. 2 is a side cross-sectional view of the vacuum furnace 1. FIGS. 3A and 3B are front cross-sectional views of the vacuum furnace 1, in which FIG. 3A is a cross-sectional view taken along the line A-A in FIG. 2 and FIG. 3B is a cross-sectional view taken along the line B-B in FIG. 2.

As illustrated in FIGS. 2 to 3B, the vacuum furnace 1 includes a vessel 11, a lateral shield plate 12, a mounting part 13, a first power feeder 14 (a first power feeding device), a second power feeder 15 (a second power feeding device), a heater 16, and a cooling device 17.

The vessel 11 has a substantially cylindrical shape forming an outer appearance of the vacuum furnace 1 and has the mounting part 13, the heater 16, and the like, received therein. A vessel having, for example, a cooling water double wall may be used as the vessel 11.

As illustrated in FIG. 2, the vessel 11 includes a horizontally opening and closing door 11a mounted at one end thereof in a horizontal direction. In addition, the opening and closing door 11a is opened such that the workpiece X may be put in and taken out of the vacuum furnace 1.

The lateral shield plate 12 is disposed to surround a region (a region of a central portion in the internal region of the vessel 11) in which the workpiece X is subjected to the plasma processing in the vessel 11, and presses a heat insulating material 12c that suppresses heat, and the like, from being transferred to the vessel 11.

Meanwhile, as illustrated in FIGS. 3A and 3B, the lateral shield plate 12 is supported by an internal panel 12b through the heat insulating material 12c, in which the internal panel 12b is fixed to the vessel 11 by a fixture 12a.

Further, the lateral shield plate 12, the internal panel 12b, and the heat insulating material 12c have a vent region, such as a through hole, so as to penetrate a gas, such as a processing gas, and the like, therethrough.

Meanwhile, as the lateral shield plate 12, for example, a carbon composite material having a thickness of about 1 mm or a molybdenum (Mo) plate having a thickness of about 0.3 mm may be used.

In addition, as the internal panel 12b, for example, an SS material or an SUS material having a thickness of about 4.5 mm to 5 mm may be used.

In addition, as the heat insulating material 12c, for example, a ceramic blanket made of aluminum oxide (Al₂O₃) may be used.

Further, in the plasma processing device S1 of the present embodiment, the vessel 11 is grounded and voltage of the vessel 11 and the shield plate 12 becomes a ground level.

The mounting part 13 mounts a tray T having the workpiece X mounted thereon in the vacuum furnace 1 and has a mounting beam 13a on which the tray T is directly mounted and a support bar 13b supporting the mounting beam 13a.

Meanwhile, the support bar 13b is made of, for example, graphite, and the like. Further, the lateral shield plate 12 is insulated from the support bar 13b by ceramics adhered to a peripheral surface of the support bar 13b or ceramics adhered to the lateral shield plate 12 so that the support bar 13b is not in an overheated state. Since the support bar 13b is insulated from the lateral shield plate 12, the overall mounting part 13 is in an insulated state.

The first power feeder 14 acts as a movable power feeding device of the present invention that applies a negative voltage (a first voltage) to the workpiece X and is configured to move in the vacuum furnace 1.

In detail, the first power feeder 14 includes a conductive bar member 14a which is inserted into the vacuum furnace 1 from the outside of the vacuum furnace 1 and conductive net members 14b which are connected to the bar member 14a. The first power feeder 14 is configured to be able to connect the conductive net members 14b to the workpiece X or any place of the tray T having the workpiece X mounted thereon.

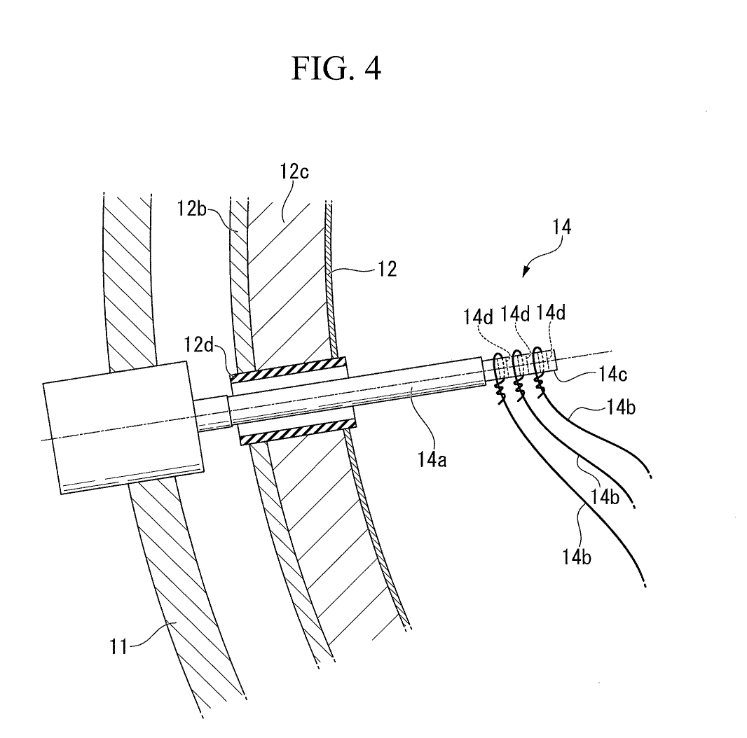

FIG. 4 is an enlarged view of a main part including the first power feeder 14.

As illustrated in FIG. 4, a ceramic tube 12d is disposed to penetrate through the internal panel 12b, the heat insulating material 12c, and the lateral shield plate 12. The bar member 14a of the first power feeder 14 is inserted up to the inside of the lateral shield plate 12 through the ceramic tube 12d. In addition, a plurality (for example, three in the present embodiment) of through holes 14d are formed in a tip portion 14c that is disposed in an inner space surrounded by the lateral shield plate 12.

The net member 14b is passed through the through hole 14d that is formed at the tip portion of the bar member 14a and bound to the bar member 14a, and thus is connected to the bar member 14a.

One net member 14b is passed through one through hole 14d and bound to the bar member 14a. That is, in the plasma processing device S1 of the present embodiment, three net members 14b may be configured to be connected to the bar member 14a.

The net member 14b may be formed using, for example, a graphite yarn.

Meanwhile, in order to exclude the influence on the plasma processing environment in the vacuum furnace 1, it is preferable to maximally suppress heat generation from the net member 14b.

A heating value of the net member 14b relies on a current density in the net member 14b. For example, in order to exclude the influence on the plasma processing environment in the vacuum furnace 1, the current density of the net member 14b may be set to be 1.2 A/mm² or less.

Table 1 shows physical property values of the graphite yarn, Table 2 shows various values when a net diameter d is set to be 10 mm, Table 3 shows various values when the net diameter d is set to be 20 mm, and Table 4 shows various values when the net diameter d is set to be 30 mm. Meanwhile, power supplied to the net member 14b has a voltage of 700 V and a current of 300 A.

TABLE 1

| Yarn diameter D | 0.8 | mm | | |
|---|---|---|---|---|
| Fineness (1000 m) de | 0.8 kg/1000 m | | 800 g/1000 m | |
| Monofilament diameter d | 0.007 | mm | 7 | μm |
| Monofilament density ρd | 1760 | kg/m³ | 1.76 | g/cm³ |
| Specific resistance ρ | 0.01 | Ω · mm | 1000 | μΩ · cm |

| Number N of monofilaments | 114 | | |
|---|---|---|---|
| included in twist yarn | | | |
| Filling rate f | 0.90 | | f = de/(ρd · 1000 · |
| | | | (π/4) · D²) |
| Cross-sectional area S of twist yarn | 0.452 | mm² | |

TABLE 2

| Diameter d of net member | 10 | mm | |
|---|---|---|---|
| Number N1 of twisted yarns | 13 | | |
| Filling rate f | 90% | | |
| Cross-sectional area S1 of net | 70.69 | mm² | S1 = d² · (π/4) · f1 |
| member | | | |
| Length L of net member | 1300 | mm | |
| Resistance R of net member | 0.184 | Ω | R = L · ρ/S |
| Heat generation amount W of net | 16.55 | kW | W = RI² |
| member | | | |
| Current density of net member | 4.24 | A/mm² | |
| Surface load density of net | 29.71 | W/cm² | |
| member | | | |

TABLE 3

| Diameter d of net member | 15 | mm |
|---|---|---|
| Number N1 of twisted yarns | 19 | |
| Filling rate f | 90% | |
| Cross-sectional area S1 of net member | 159.04 | mm² |
| Length L of net member | 1300 | mm |
| Resistance R of net member | 0.082 | Ω |
| Heat generation amount W of net member | 7.36 | kW |
| Current density of net member | 1.89 | A/mm² |
| Surface load density of net member | 13.20 | W/cm² |

TABLE 4

| Diameter d of net member | 20 | mm |
|---|---|---|
| Number N1 of twisted yarns | 25 | |
| Filling rate f | 90% | |
| Cross-sectional area S1 of net member | 282.74 | mm² |
| Length L of net member | 1300 | mm |
| Resistance R of net member | 0.046 | Ω |
| Heat generation amount W of net member | 4.14 | kW |
| Current density of net member | 1.06 | A/mm² |
| Surface load density of net member | 7.43 | W/cm² |

As shown in Tables 1 to 4, when the net diameter d is set to be 20 mm, a cross-sectional area of the net member becomes 282.74 and a current density becomes 1.06 A/mm² to meet conditions of 1.2 A/mm² as described above. Therefore, by setting the net diameter d to be 20 mm, only one net member 14b may feed power to the workpiece X without affecting the plasma processing environment.

Further, in the plasma processing device S1 of the present embodiment, as described above, three net members 14b are configured to be connected to the bar member 14a in parallel with each other. Therefore, it is preferable to install a plurality of net members 14b each of whose weight is reduced, rather than mounting only one net member having a net diameter d of 20 mm.

In detail, at the time of installing the plurality of net members 14b, a net diameter d2, and the like, of each of the net members 14b may be set as shown in the following Tables 5 and 6.

TABLE 5

| Number N2 of net members | 2 | | |
|---|---|---|---|
| Cross-sectional area S2 required for | 141.37 | mm² | S2 = S1/N2 |
| one net member | | | |
| Diameter d2 of net member | 13.42 | mm | S2 = d2² · π/4 |

| | | |
|---|---|---|
| Required number n2 of twisted yarns | 17 | n2 = d2/D |

TABLE 6

| Number N2 of net members | 3 | |
|---|---|---|
| Cross-sectional area S2 required for one net member | 94.25 | mm² |
| Diameter d2 of net member | 10.95 | mm |

| | |
|---|---|
| Required number n2 of twisted yarns | 14 |

Further, in the plasma processing device S1 of the present embodiment, the first power feeder 14 is disposed to be closer to the opening and closing door 11a than a center of the vacuum furnace 1.

In detail, the first power feeder 14 is disposed at a position at which a worker's hand reaches the net member 14b of the first power feeder 14, in a state in which the workpiece X is received in the vacuum furnace 1 and when the opening and closing door 11a is opened.

The second power feeder 15 supports the lateral shield plate 12, and acts as a movable power feeding device of the present invention that feeds a ground level of voltage (a second voltage) to the lateral shield plate 12 and is configured to move in the vacuum furnace 1.

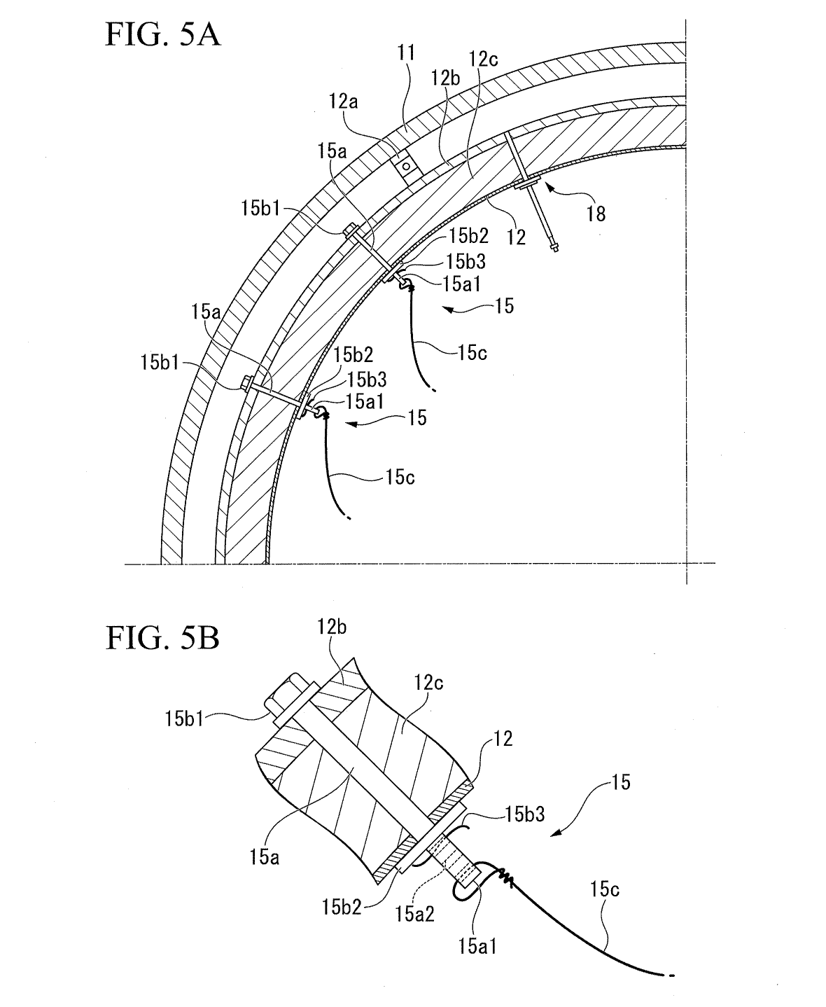

FIGS. 5A and 5B are enlarged views including the second power feeder 15, in which FIG. 5A is an enlarged view of a part of the vacuum furnace including the second power feeder 15 and FIG. 5B is an enlarged view of only the second power feeder 15.

As illustrated in FIGS. 5A and 5B, in the plasma processing device S1 of the present embodiment, the second power feeder 15 includes a bar member 15a, a fixed member 15b, and a net member 15c.

The conductive bar member 15a penetrates through the internal panel 12b, the heat insulating material 12c, and the lateral shield plate 12, and a tip portion 15a1 thereof is disposed in an inner space surrounded by the lateral shield plate 12. The bar member 15a is made of, for example, a molybdenum (Mo) material or a carbon composite.

Further, a plurality of through holes 15a2 into which the net member 15c is inserted are formed at the tip portion 15a1 of the bar member 15a.

The fixed member 15b fixes the bar member 15a. The fixed member 15b includes a bolt 15b1 that fixes the bar member 15a to the internal panel 12b, a stop plate 15b2 through which the bar member 15a is penetrated and contacts an inner wall of the lateral shield plate 12, and a wire member 15b3 which is inserted into one of the through holes 15a2 and fixes the bar member 15a through the stop plate 15b2.

Meanwhile, the stop plate 15b2 is made of, for example, a carbon composite and the wire member 15b3 is made of a molybdenum (Mo) material.

The net member 15c is configured to have one end that is inserted into the through hole 15a2 formed at the tip portion 15a1 of the bar member 15a and the other end that is connectable to a post-attached electrode (attaching electrode 100) to be described below. An example of the post-attached electrode may include an arc electrode.

The net member 15c may be freely movable in the vacuum furnace 1. Therefore, the net member 15c may be connected to the attaching electrode 100 in consideration of only a length, regardless of the shape of the attaching electrode 100.

Further, for example, the number of second power feeders 15 is set so that the current density of each second power feeder 15 does not affect the plasma formation environment of the vacuum furnace 1.

In detail, the number of second power feeders 15 is set so that the current density of the net member 15c is 1.2 A/mm² or less.

In addition, in the plasma processing device S1 of the present embodiment, as illustrated in FIG. 5A, a hanger 18 is disposed together with the second power feeder 15.

The hanger 18 is a fixture that hangs the attaching electrode 100 on the inside of the vacuum furnace 1. The hanger 18 is formed by extending a pin member 12c protruding from the internal panel 12b to support the lateral shield plate 12 up to the inside of the lateral shield plate 12. Meanwhile, the tip portion of the hanger 18 is provided with a screw fastened with a nut so as to easily attach the attaching electrode 100, thereby having a concavo-convex shape.

In addition, in the plasma processing device S1 of the present embodiment, as illustrated in FIGS. 3A and 3B, the attaching electrode 100 (a metal body) is configured to be attached to the inside of the vacuum furnace 1.

The attaching electrode 100 is supported by being hung by the hanger 18 and is connected to the net member 15c such that a ground level of voltage from the second power feeder 15 is applied thereto.

Meanwhile, the shape of the attaching electrode 100 illustrated in FIGS. 3A and 3B is one example and may be optionally changed so as to be applied to the shape of the workpiece X, and the like.

This will be described by referring back to FIG. 2. As illustrated in FIG. 2, the heater 16 heats the workpiece X which is mounted in the vacuum furnace 1. When viewed from the opening and closing door 11a side of the vacuum furnace 1, a plurality (for example, six in the present embodiment) of heaters 16 are arranged. As illustrated in FIG. 3A, each heater 16 is disposed in an annular shape by surrounding a region (a central region in the inner region of the vessel 11) in which the workpiece X is subjected to the plasma processing.

The cooling device 17 circulates and cools a cooling gas supplied into the vessel 11. The cooling device 17 includes a fan 17a that circulates the cooling gas, a motor 17b that rotatably drives the fan 17a, a heat exchanger 17c that cools the cooling gas, and the like.

Referring back to FIG. 1, the vacuum pump 2 is connected to an exhaust port 11b (see FIGS. 3A and 3B) of the vessel 11 to exhaust a gas in the vessel 11.

The processing gas supply device 3 is connected to the vessel 11 to supply a processing gas (a carburization gas) into the vessel 11.

The cooling gas supply device 4 is connected to a header pipe, and the like, disposed in the vessel 11 to supply the cooling gas into the vessel 11.

The power supply device 5 is electrically connected to the first power feeder 14 and generates the negative voltage applied to the tray T through the first power feeder 14.

The control device 6 controls the entire operation of the plasma processing device S1 of the present embodiment. The control device 6 is electrically connected to the vacuum furnace 1, the vacuum pump 2, the processing gas supply device 3, the cooling gas supply device 4, and the power supply device 5.

Next, an operation of the plasma processing device S1 of the present embodiment having the foregoing configuration will be described.

Meanwhile, a case of attaching the attaching electrode 100 and performing the plasma processing will be described.

First, the tray T having the workpiece X mounted thereon is received in the vacuum furnace 1. In detail, the workpiece X is received in the vacuum furnace 1 by mounting the tray T on the mounting part 13.

Next, the attaching electrode 100 is attached. In detail, the attaching electrode 100 is hung on the hanger 18 and the net member 15c of the second power feeder 15 is connected to the attaching electrode 100.

Meanwhile, the attaching electrode 100 hung by the hanger 18 is disposed to face the workpiece X in a contactless manner. Further, a ground level of voltage is applied to the hung attaching electrode 100 through the second power feeder 15.

Then, the net member 14b of the first power feeder 14 is connected to the tray T. Meanwhile, the net member 14b of the first power feeder 14 has a wire-harness shape having a connector and the tray T is provided with a connector that can be connected to the connector of the net member 14b. As a result, the net member 14b can be easily connected to the tray T.

The workpiece X is received in the vacuum furnace 1, the attaching electrode 100 is attached to the vacuum furnace 1, and the opening and closing door 11a of the vessel 11 is closed. Then, the control device 6 performs heat treatment, plasma processing, and cooling treatment on the workpiece X based on instructions from an operation device (not illustrated), and the like.

For example, the control device 6 controls the heater 16 to heat the workpiece X when the heat treatment is performed on the workpiece X.

In detail, the control device 6 controls the vacuum pump 2 to exhaust air in the vessel 11 and the processing gas supply device 3 to supply the processing gas into the vessel 11. In addition, the control device 6 generates heat in the heater 16 to heat the workpiece X.

Further, the control device 6 controls the power supply device 5 to apply the negative voltage to the workpiece X through the first power feeder 14 when the workpiece X is subjected to the plasma processing.

As a result, the processing gas is in a plasma state due to an electric field that is generated between the workpiece X and the attaching electrode 100 to expose the surface of the workpiece X such that the exposed surface is subjected to the plasma processing.

In addition, the control device 6 controls the cooling device 17 to cool the workpiece X when the cooling processing is performed on the workpiece X.

In detail, the control device 6 controls the vacuum pump 2 to exhaust the processing gas in the vessel 11 and the cooling gas supply device 4 to supply the cooling gas into the vessel 11. In addition, the control device 6 controls the cooling device 17 to cool and circulate the cooling gas, thereby cooling the workpiece X.

In addition, when the heat treatment, the plasma processing, and the cooling treatment on the workpiece X are completed, the inside of the vessel 11 is opened to an atmosphere by opening the opening and closing door 11a and the workpiece X is taken out together with the tray T.

In the plasma processing device S1 of the above-mentioned present embodiment, the first power feeder 14 that applies the negative voltage (first voltage) to the workpiece X and the second power feeder 15 that applies the ground level of voltage (the second voltage) to the attaching electrode 100 disposed to face the workpiece X are configured as the movable power feeding device that can be movable in the vacuum furnace 1.

According to the plasma processing device S1 of the present embodiment, a feeding point to the tray T or the attaching electrode can be easily changed. Therefore, strength of an electric field for generating plasma can be changed optionally. As a result, measures adaptive to the change in the shape of the workpiece X, and the like, may be easily performed and the degree of freedom in the surface reforming of the workpiece X can be improved.

In addition, in the plasma processing device S1 of the present embodiment, the first power feeder 14 includes the conductive bar member 14a which is inserted into the vacuum furnace 1 from the outside of the vacuum furnace 1 and the conductive net member 14b which is connected to the bar member 14a.

Therefore, the first power feeder 14 can be connected at any point on the tray T by moving the tip portion of the net member 14b.

In addition, in the plasma processing device S1 of the present embodiment, the plurality of net members 14b are disposed.

Therefore, each of the net members 14b can be lightweight.

Further, in the plasma processing device S1 of the present embodiment, the first power feeder 14 is disposed to be closer to the opening and closing door 11a than the center of the vacuum furnace 1.

Therefore, a worker can easily perform a connection operation on the first power feeder 14 and the tray T.

Further, in the plasma processing device S1 of the present embodiment, the attaching electrode 100 is used as a metal body which is capable of being attached to/detached from the second power feeder 15 and is fed by the second power feeder 15.

Therefore, a spaced distance between the attaching electrode 100 and the workpiece X, that is, a spaced distance between a positive electrode and a negative electrode, can be narrow. As a result, the strength of an electric field generated between the attaching electrode 100 and the workpiece X can be increased and plasma can be generated effectively.

Further, in the plasma processing device S1 of the present embodiment, the mounting part 13 having the workpiece X mounted thereon in the vacuum furnace 1 is electrically insulated.

Therefore, the mounting part 13 can be suppressed from being charged, and dust, and the like, can be suppressed from being attached to the mounting part 13.

In addition, the plasma processing device S1 of the present embodiment includes the heater 16 which is installed in the vacuum furnace 1, the processing gas supply device 3 (the carburization gas supply device) that supplies the processing gas (the carburization gas) into the vacuum furnace 1, and the cooling device 17 (the cooling device) that cools the inside of the vacuum furnace 1.

Therefore, the heater 16 can increase temperature to the temperature at which the plasma processing can be stably performed. As a result, a single plasma processing device S1 can perform the heat treatment, the plasma processing, and the cooling treatment on the workpiece X.

Although the exemplary embodiments of the present invention are described with reference to the drawings, the present invention is not limited to the foregoing embodiments. All the shapes or combinations of each component described in the foregoing embodiments are by way of example only, and therefore may be variously changed based on the design demand, and the like, without departing from the gist of the present invention.

For example, the foregoing embodiment describes a single room type plasma processing device including only one vacuum furnace 1.

However, the present invention is not limited thereto, and may be applied to a multi-room type plasma processing device that may include the plurality of vacuum furnaces 1 to perform the plasma processing on the plurality of workpieces X in parallel.

Further, in the foregoing embodiment, for example, the movable power feeding device of the present invention includes the net members 14b and 15b, such that the movable power feeding device is configured to move in the vacuum furnace 1.

However, the present invention is not limited thereto, and the bar member may be rotatably or slidably configured, a plate member or a bar member having flexibility may be used instead of the net member, or a stripe member may be used, such that the movable power feeding device is configured to move in the vacuum furnace 1.

Further, the embodiment is described under the premise that all the net members 14b are connected to the tray T and all the net members 15c are connected to the attaching electrode 100.

However, it is not necessary to connect all the net members 14b to the tray T and all the net members 15c to the attaching electrode 100.

However, in order for the net member 14b that is not connected to the tray T or the net member 15c that is not connected to the attaching electrode 100 to be exposed during the treatment of the workpiece, it is preferable to take a measure of rolling the net members 14b and 15c that are not be connected to the tray T or the attaching electrode 100 or attaching a counter weight to the net members 14b and 15c that are not connected to the tray T or the attaching electrode 100.

In addition, the foregoing embodiments describe a configuration of using the attaching electrode 100 as the positive electrode by attaching the attaching electrode 100 in which a ground level of charge is applied to the workpiece X to which the negative charge is applied.

However, the present invention is not limited thereto, and the lateral shield plate 12 may be used as the positive electrode without attaching the attaching electrode 100.

### INDUSTRIAL APPLICABILITY

According to the present invention, the power feeding point to the tray or the inner wall of the vacuum furnace can be changed using the movable power feeding device. Further, the metal body having any shape is disposed to face the workpiece, such that power may be fed to the metal body. In addition, the strength of an electric field for generating plasma can be optionally changed and the degree of freedom in the surface reforming of the workpiece can be improved.

### REFERENCE SIGNS LIST

S1: plasma processing device
1: vacuum furnace
3: processing gas supply device (carburization gas supply device)
11: vessel
11a: opening and closing door
12: lateral shield plate
13: mounting part
14: first power feeder (first power feeding device)
14a: bar member
14b: net member
15: second power feeder (second power feeding device)
16: heater
17: cooling device (cooling device)
T: tray
X: workpiece

1. A plasma processing device configured to perform surface reforming on a workpiece made of a metal material in a vacuum furnace by plasma, the plasma processing device comprising:
a first power feeding device that applies a first voltage to the workpiece; and
a second power feeding device that applies a second voltage different from the first voltage to a metal body disposed to face the workpiece,
wherein at least one of the first power feeding device and the second power feeding device is configured as a movable power feeding device that is movable in the vacuum furnace.

2. The plasma processing device according to claim 1, wherein the movable power feeding device includes a conductive bar member which is inserted into the vacuum furnace from an outside of the vacuum furnace and a conductive net member which is connected to the bar member.

3. The plasma processing device according to claim 2, wherein a plurality of the net members are provided.

4. The plasma processing device according to claim 1, wherein the movable power feeding device is disposed to be closer to an opening and closing door than a center of the vacuum furnace.

5. The plasma processing device according to claim 1, wherein the metal body to which the second voltage is applied by the second power feeding device is an electrode which is detachably put in and taken out of the vacuum furnace.

6. The plasma processing device according to claim 1, wherein a mounting part that mounts the workpiece in the vacuum furnace is insulated.

7. The plasma processing device according to claim 1, further comprising a heater which is installed in the vacuum furnace, a carburization gas supply device that supplies a carburization gas to an inside of the vacuum furnace, and a cooling device that cools the inside of the vacuum furnace.
